(19) United States
(12) Patent Application Publication
(10) Pub. No.: US 2021/0249326 A1
(43) Pub. Date: Aug. 12, 2021

(54) HEAT DISSIPATION DEVICES HAVING THERMAL INTERFACE MATERIAL CONTAINMENT STRUCTURES

(71) Applicant: Intel Corporation, Santa Clara, CA (US)

(72) Inventors: Aastha Uppal, Chandler, AZ (US); Je-Young Chang, Tempe, AZ (US)

(73) Assignee: Intel Corporation, Santa Clara, CA (US)

(21) Appl. No.: 16/789,322

(22) Filed: Feb. 12, 2020

(51) Int. Cl. H01L 23/367; H01L 21/48; H01L 23/00

(52) U.S. Cl. CPC H01L 23/367; H01L 21/4871; H01L 2224/32258; H01L 2224/32257; H01L 24/32

(57) ABSTRACT

An integrated circuit assembly may be formed comprising at least one integrated circuit device, a heat dissipation device having a thermal contact surface with at least one containment structure extending into or from the heat dissipation device at the thermal contact surface, and a thermal interface material between the at least one integrated circuit device and the heat dissipation device, wherein the thermal interface material contacts the at least one containment structure of the heat dissipation device.

### TECHNICAL FIELD

Embodiments of the present description generally relate to the field of thermal management for integrated circuit packages, and, more specifically, to a heat dissipation device having structures for thermal interface material containment.

### BACKGROUND

The integrated circuit industry is continually striving to produce ever faster, smaller, and thinner integrated circuit (IC) devices and packages for use in various electronic products, including, but not limited to, computer servers and portable products, such as portable computers, electronic tablets, cellular phones, digital cameras, and the like.

As these goals are achieved, the integrated circuit devices become smaller. Accordingly, the density of power consumption of electronic components within the integrated circuit devices has increased, which, in turn, increases the average junction temperature of the integrated circuit device. If the temperature of the integrated circuit device becomes too high, the integrated circuits may be damaged or destroyed. Thus, heat dissipation devices are used to remove heat from the integrated circuit devices in an integrated circuit package. In one example, at least one integrated circuit device may be mounted to a substrate and the heat dissipation device may be thermally attached to the at least one integrated circuit device with a thermal interface material (TIM) that is disposed between the integrated circuit device(s) and the heat dissipation device to form thermal contact therebetween. The distance between the integrated circuit device(s) and the heat dissipation device is known as the bond line thickness (BLT).

The thermal interface material primarily serves two functions: 1) to provide a heat transfer path from the integrated circuit device(s) to the heat dissipation device, and 2) to help absorb stresses in the integrated circuit package caused by differing thermal expansions between the components therein. With regard to providing a heat transfer path, the thermal efficiency of the thermal interface material is critical to effectively remove heat from the integrated circuit device(s). The thermal interface material may include thermal greases, gap pads, polymers, and the like. Although these thermal interface materials have advantages, they also have intrinsic material properties on exposure to thermo-mechanical stresses which can result in “failure modes”. These failure modes can include voiding, which can result in delamination from the heat dissipation device and/or the integrated circuit device(s); hardening, which can lead to loss of adhesion that can also result in delamination from the heat dissipation device and/or the integrated circuit devices; and pump-out, where the thermal interface material physically moves out from between the heat dissipation device and the integrated circuit device(s). The thermo-mechanical stresses that cause failure modes result from temperature cycles during the operation of the integrated circuit package, manufacturing processes, and shipping. The temperature cycles cause warpage in integrated circuit device(s) within the integrated circuit package when it heats and cools during operation. For example, in a standard integrated circuit package with one integrated circuit device, the heat dissipation device bottoms out at approximately the center of the integrated circuit device, due to the integrated circuit device's natural convex shape at room temperature. When the integrated circuit package is exposed to temperature gradients, the shape of the integrated circuit device changes from convex to flat or concave, which causes compression on the thermal interface material at edges or sidewalls of the integrated circuit device. When the integrated circuit package returns to room temperature, the integrated circuit device returns to a convex shape creating an elongation of the thermal interface material at the edge or sidewalls of the integrated circuit device. The mechanisms of compression and elongation may cause the previously discussed failure modes.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly, according to one embodiment of the present description.

FIGS. 2 and 3 are plan views of a heat dissipation device along line 2-2 of FIG. 1, according to embodiments of the present description.

FIGS. 4 and 5 are cross-sectional views of a heat dissipation device, according to embodiments of the present description.

FIG. 6 is a side cross-sectional view of an integrated circuit assembly, according to one embodiment of the present description.

FIGS. 7 and 8 are plan views of a heat dissipation device along line 7-7 of FIG. 6, according to embodiments of the present description.

FIGS. 9-11 are cross-sectional views of an integrated circuit assembly, according to other embodiments of the present description.

FIG. 12 is a flow chart of a process of fabricating an integrated circuit assembly, according to an embodiment of the present description.

FIG. 13 is an electronic system, according to one embodiment of the present description.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-bond interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures, as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description include an integrated circuit assembly comprising at least one integrated circuit device, a heat dissipation device having a thermal contact surface with at least one containment structure extending into or from the heat dissipation device at the thermal contact surface, and a thermal interface material between the at least one integrated circuit device and the heat dissipation device, wherein the thermal interface material contacts the at least one containment structure of the heat dissipation device.

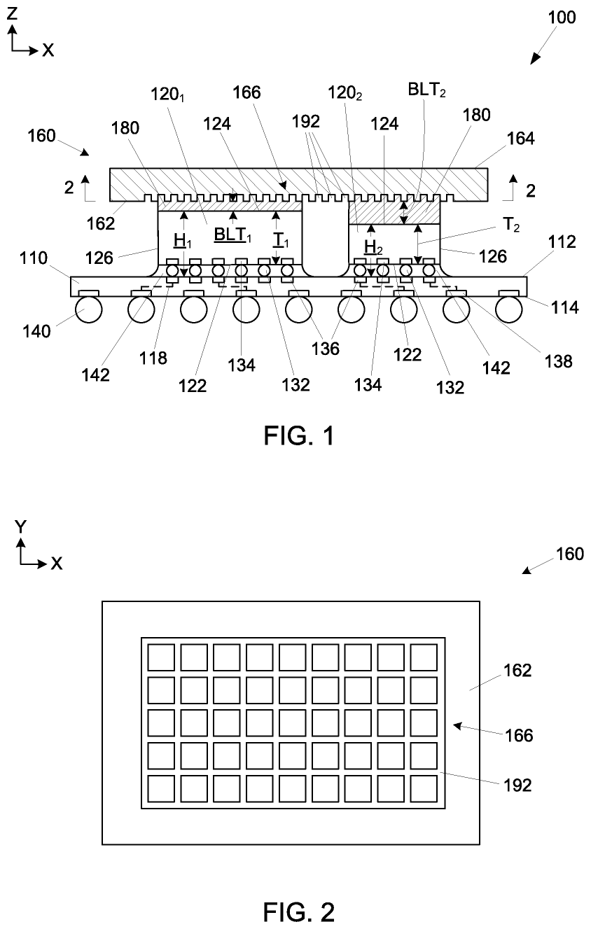

FIG. 1 illustrates an integrated circuit assembly 100 having at least one integrated circuit device (illustrated as a first integrated circuit device 120₁ and a second integrated circuit device 120₂) electrically attached to an electronic substrate 110 in a configuration generally known as a flip-chip or controlled collapse chip connection (“C4”) configuration, according to an embodiment of the present description.

The electronic substrate 110 may be any appropriate structure, including, but not limited to, an interposer. The electronic substrate 110 may have a first surface 112 and an opposing second surface 114. The electronic substrate 110 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like.

The electronic substrate 110 may further include conductive routes 118 or “metallization” (shown in dashed lines) extending through the electronic substrate 110. As will be understood to those skilled in the art, the conductive routes 118 may be a combination of conductive traces (not shown) and conductive vias (not shown) extending through the plurality of dielectric material layers (not shown). These conductive traces and conductive vias are well known in the art and are not shown in FIG. 1 for purposes of clarity. The conductive traces and the conductive vias may be made of any appropriate conductive material, including but not limited to, metals, such as copper, silver, nickel, gold, and aluminum, alloys thereof, and the like. As will be understood to those skilled in the art, the electronic substrate 110 may be a cored substrate or a coreless substrate.

The first integrated circuit device 120₁ and the second integrated circuit device 120₂ may be any appropriate device, including, but not limited to, a microprocessor, a chipset, a graphics device, a wireless device, a memory device, an application specific integrated circuit, combinations thereof, stacks thereof, or the like. As shown, the first integrated circuit device 120₁ and the second integrated circuit device 120₂ may each have a first surface 122, an opposing second surface 124, and at least one side 126 extending between the first surface 122 and the second surface 124.

As will be understood, when multiple integrated circuit devices are utilized, they may have different thicknesses. For example, as shown in FIG. 1, the first integrated circuit device 120₁ and the second integrated circuit device 120₂ may have differing thicknesses T₁ and T₂, respectively, that is measured from the first surface 122 to the second surface 124 of the first integrated circuit device 120₁ and the second integrated circuit device 120₂, respectively. The differing thicknesses T₁ and T₂ may result in differing heights H₁ and H₂ between the first integrated circuit device 120₁ and the second integrated circuit device 120₂, respectively, that is measured from the first surface 112 of the electronic substrate 110 to the second surface 124 of each of the first integrated circuit device 120₁ and the second integrated circuit device 120₂, respectively, which may result in differing bond line thickness BLT¹ and BLT², respectively.

In an embodiment of the present description, the first integrated circuit device 120₁ and the second integrated circuit device 120₂ may be electrically attached to the electronic substrate 110 with a plurality of device-to-substrate interconnects 132. In one embodiment of the present description, the device-to-substrate interconnects 132 may extend between bond pads 136 on the first surface 112 of the electronic substrate 110 and bond pads 134 on the first surface 122 of the first integrated circuit device 120₁ and on the first surface 122 of the second integrated circuit device 120₂. The device-to-substrate interconnects 132 may be any appropriate electrically conductive material or structure, including, but not limited to, solder balls, metal bumps or pillars, metal filled epoxies, or a combination thereof. In one embodiment, the device-to-substrate interconnects 132 may be solder balls formed from tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys). In another embodiment, the device-to-substrate interconnects 132 may be copper bumps or pillars. In a further embodiment, the device-to-substrate interconnects 132 may be metal bumps or pillars coated with a solder material.

The bond pads 134 may be in electrical communication with integrated circuitry (not shown) within their respective integrated circuit devices, i.e. the first integrated circuit device 120₁ and the second integrated circuit device 120₂. The bond pads 136 on the first surface 112 of the electronic substrate 110 may be in electrical contact with the conductive routes 118. The conductive routes 118 may extend through the electronic substrate 110 and be connected to bond pads 138 on the second surface 114 of the electronic substrate 110. As will be understood to those skilled in the art, the electronic substrate 110 may reroute a fine pitch (center-to-center distance between the bond pads) of the integrated circuit device bond pads 136 to a relatively wider pitch of the bond pads 138 on the second surface 114 of the electronic substrate 110. In one embodiment of the present description, external interconnects 140 may be disposed on the bond pads 138 on the second surface 114 of the electronic substrate 110. The external interconnects 140 may be any appropriate electrically conductive material, including, but not limited to, metal filled epoxies and solders, such as tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys). The external interconnects 140 may be used to attach the integrated circuit assembly 100 to an external substrate (not shown), such as a motherboard.

An electrically-insulating underfill material 142, such as an epoxy material, may be disposed between the first integrated circuit device 120₁ and the electronic substrate 110, and between the second integrated circuit device 120₂ and the electronic substrate 110. The underfill material 142 may be used to overcome the mechanical stress issues that can arise from thermal expansion mismatch between the electronic substrate 110 and the integrated circuit devices 120₁ and 120₂. As will be understood to those skilled in the art, the underfill material 142 may be dispensed between the first surface 122 of the integrated circuit devices 120₁, 120₂, respectively, and the electronic substrate 110 as a viscous liquid and then hardened with a curing process.

As further shown in FIG. 1, the integrated circuit assembly 100 may further include a heat dissipation device 160 having a thermal contact surface 162 that is thermally coupled with the second surface 124 of the first integrated circuit device 120₁ and the second surface 124 of the second integrated circuit device 120₂ with a thermal interface material 180. The heat dissipation device 160 may be a heat pipe, a vapor chamber, a liquid cooling device, a cold plate, and the like. In one embodiment, the heat dissipation device 160 may be made of any appropriate thermally conductive material, including, but not limited to at least one metal material and alloys of more than one metal, or highly doped glass or highly, conductive ceramic material, such as aluminum nitride. In a specific embodiment of the present description, the heat dissipation device 160 may comprise copper, nickel, aluminum, alloys thereof, laminated metals including coated materials (such as nickel coated copper), and the like. When the heat dissipation device 160 is a cold plate, at least one additional thermal management device (not shown) may be attached to an exterior surface 164 of the heat dissipation device 160 to enhance heat removal. Such additional thermal management devices may include, but are not limited to, heat pipes, high surface area dissipation structures with a fan (such as a structure having fins or pillars/columns formed in a thermally conductive structure), liquid cooling devices, and the like.

In various embodiments of the present description, the thermal interface material 180 may be any appropriate, thermally conductive material, including, but not limited to, a thermal grease, a thermal gap pad, a polymer, an epoxy filled with high thermal conductivity fillers, such as metal particles or silicon particles, and the like. In one embodiment of the present description, the thermal interface material 180 may be a phase change material. A phase change material is a substance with a high heat of fusion, which, when it melts and solidifies, is capable of storing and releasing large amounts of thermal energy. In an embodiment of the present description, the phase change material may include, but not limited to, nonadecane, decanoic (capric) acid, eicosane, dodecanoic (lauric) acid, docosane, paraffin wax, stearic acid, tetradecanoic (myristic) acid, octadecanol, hexadecanoic (palmitic) acid, and metallic alloys which include one or more of bismuth, lead, tin, cadmium, antimony, indium, thallium, tellurium, selenium, gallium, mercury, and combinations thereof.

As previously discussed, the integrated circuit assembly 100 goes through temperature cycling and warpage during use and the thermal interface material 180 may squeeze or pump out from between the heat dissipation device 160 and the at least one integrated circuit device 120₁, 120₂, which may lead to voids in the thermal interface material 180 thereby increasing thermal resistance. In embodiment of the present description, a containment structure 166 comprising at least one recess 192 may be formed in the thermal contact surface 162 of the heat dissipation device 160. The formation of the containment structure 166 increases the frictional surface area of the thermal contact surface 162. Thus, the increase surface area will act to prevent the thermal interface material 180 from squeezing or pumping out. Therefore, the formation of the containment structure 166 will allow for a greater variety of types of thermal interface materials 180 and provides flexibility with different die heights H₁, H₂ and different bond line thickness BLT₁, BLT₂ requirements.

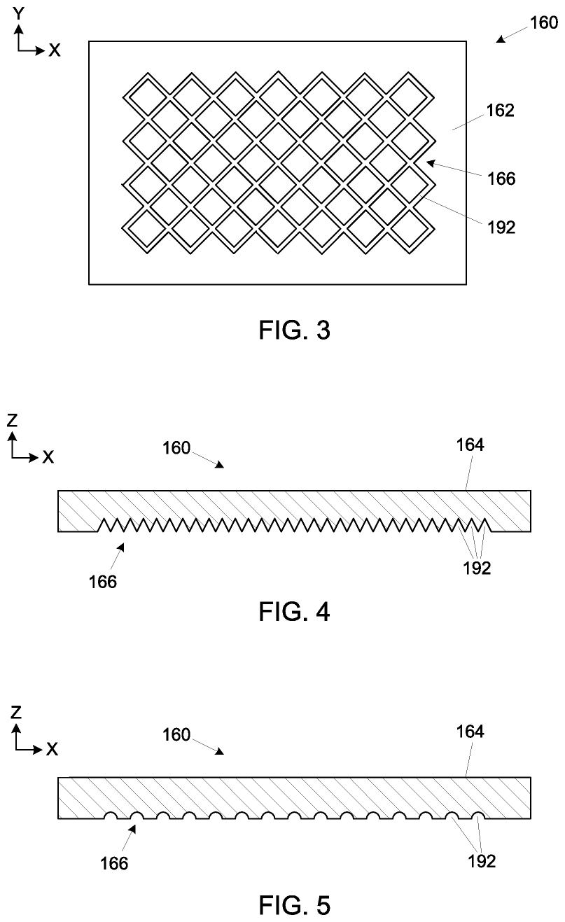

The at least one recess 192 may be formed by any appropriate process, including, but not limited to, etching, laser scribing, ion ablation, stamping, skiving, molding (e.g. during the fabrication of the heat dissipation device 160), and the like. The at least one recess 192 may have any appropriate pattern. In one example, as shown in FIG. 2, the at least one recess 192 may form a “checker board” pattern. In another example, as shown in FIG. 3, the at least one recess 192 may form a diamond or knurled pattern. Although FIG. 1 illustrates the cross-section shape of the at least one recess 192 as substantially rectilinear, the embodiments of the present description are not so limited, as the at least one recess 192 may have any appropriate cross-sectional shape. It is understood that the cross-sectional shape of the at least one recess 192 may be dictated by the process used for its formation. In one example, as shown in FIG. 4, the at least one recess 192 may have a substantially triangular cross-sectional shape. In another example, as shown in FIG. 5, the at least one recess 192 may have a substantially arcuate cross-sectional shape.

It is understood that the design and patterning of the recesses 192 may be optimized to ensure that potential pump-out of the thermal interface material 180 is substantially contained and to ensure that the initial thermal performance of the thermal interface material 180 is not significantly degraded. Factors that may be considered in the optimization may include, but are not limited to, an area of the second surface 124 of the integrated circuits devices 120₁ and 120₂, the material used for the thermal interface material 180, the anticipated warpage of the integrated circuit assembly 100, and the like. It is further understood that the inclusion of containment structure 166 may help mitigate manufacturing variations in the specifications of the heat dissipation device design, like planarity, flatness, and the like.

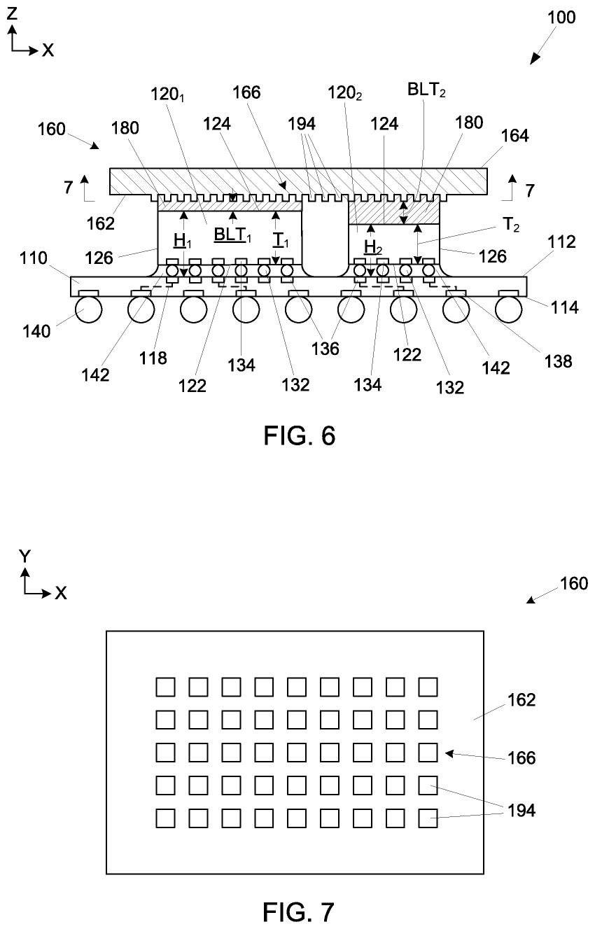

In further embodiments of the present description, as shown in FIGS. 6-8, the containment structure 166 may comprise a plurality of projections 194 extending from the thermal contact surface 162 of the heat dissipation device 160. The formation of the containment structure 166 with the plurality of projections 194 increases the frictional surface area of the thermal contact surface 162. Thus, the increase surface area will act to prevent the thermal interface material 180 from squeezing or pumping out, as previously discussed.

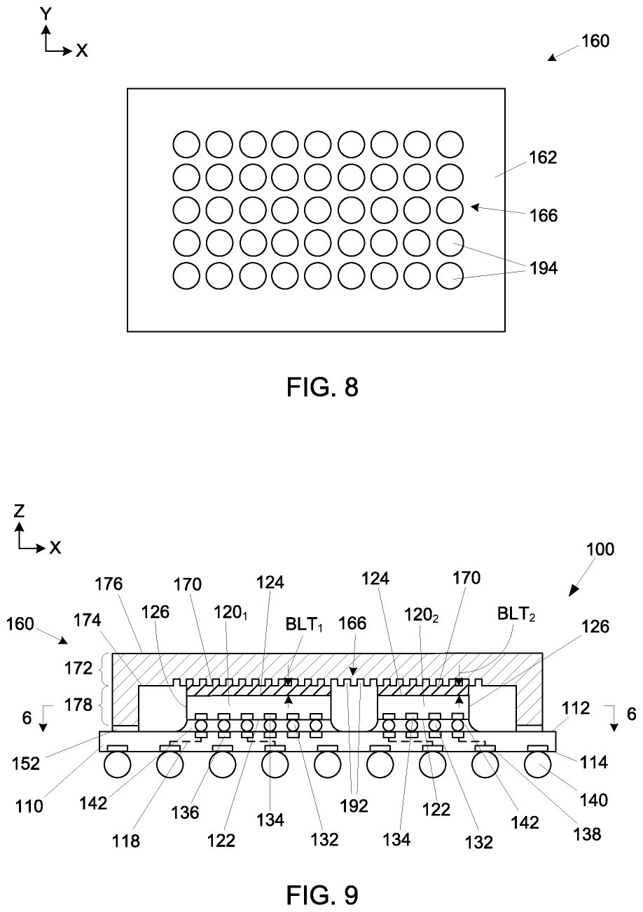

The plurality of projections 192 may be formed by any appropriate process, including, but not limited to, plating, attachment, etching, laser scribing, ion ablation, stamping, skiving, molding (e.g. during the fabrication of the heat dissipation device 160), and the like. The plurality of projections 194 may have any appropriate pattern and cross-sectional shape. In one example, as shown in FIG. 7, the plurality of projections 194 may be arranged in ordered rows and columns, and may each have a substantially square cross-sectional shape. In another example, as shown in FIG. 8, the plurality of projections 194 may be arranged in ordered rows and columns, and may each have a substantially circular cross-sectional shape. Furthermore, although the plurality of projections 194 are illustrated in FIGS. 8 and 9 as ordered pillars, the embodiments of the present description are not so limited and may include non-ordered strings, filaments, and the like.

It is understood that the design and patterning of the plurality of projections 194 may be optimized to ensure that potential pump-out of the thermal interface material 180 is substantially contained and to ensure that the initial thermal performance of the thermal interface material 180 is not significantly degraded. Factors that may be considered in the optimization are the same as those for the embodiment discussed with regard to FIG. 1-5.

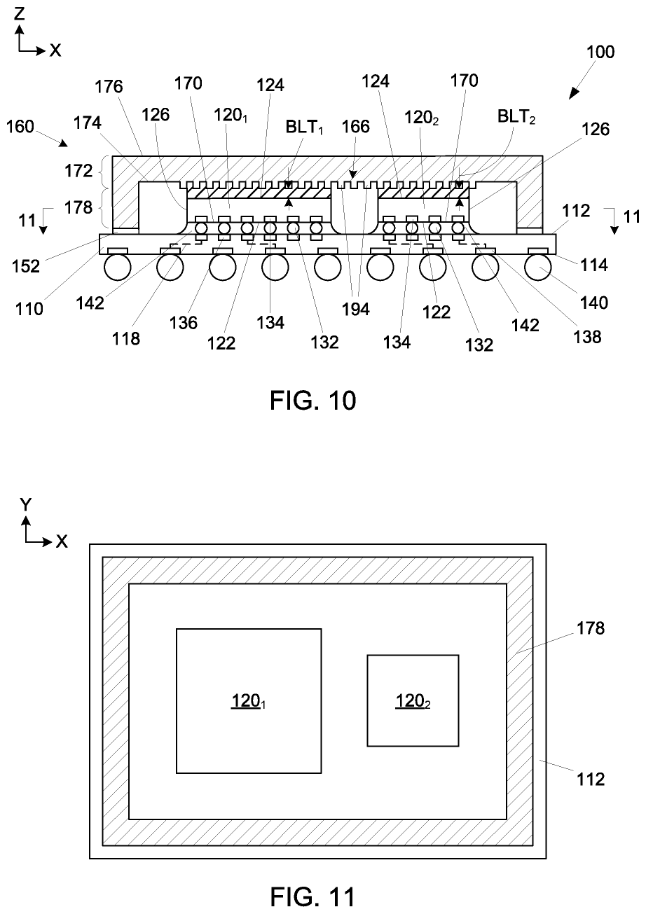

Although the heat dissipation device 160 of FIG. 1 is illustrated as a substantially planar structure, the embodiments of the present description are not so limited, and may be any appropriate configuration. For example, the heat dissipation device 160 may be an integrated heat spreader, as shown in FIGS. 9-11. In one embodiment of the present description, the heat dissipation device 160 may comprise a main body 172, having a thermal contact surface 174 and an opposing surface 176, and at least one boundary wall 178 extending from the thermal contact surface 174 of the main body 172 of the heat dissipation device 160. The at least one boundary wall 178 may be attached or sealed to the first surface 112 of the electronic substrate 110 with an attachment adhesive or sealant layer 152. The heat dissipation device 160 may be made of any appropriate thermally conductive material, including, but not limited to, at least one metal material and alloys of more than one metal, or highly doped glass or highly conductive ceramic material, such as aluminum nitride. In a specific embodiment of the present description, the heat dissipation device 160 may comprise copper, nickel, aluminum, alloys thereof, laminated metals including coated materials (such as nickel coated copper), and the like. FIG. 9 illustrates the containment structure 166 of the heat dissipation device 160 as being formed with at least one recess 192, and FIG. 10 illustrates the containment structure 166 of the heat dissipation device 160 as being formed with a plurality of projections 194.

As illustrated in FIGS. 9 and 10, the heat dissipation device 160 may be a single material throughout, such as when the heat dissipation device 160 including the heat dissipation boundary wall 178 is formed by a single process step, including but not limited to, stamping, skiving, molding, and the like. However, embodiments of the present description may also include heat dissipation device 160 made of more than one component. For example, the heat dissipation device boundary wall 178 may be formed separately from the main body 172, then attached together to form the heat dissipation device 160. In one embodiment shown in FIG. 11, the boundary wall 178 may be a single “picture frame” structure surrounding the first integrated circuit device 120₁ and the second integrated circuit device 120₂.

The attachment adhesive 152 may be any appropriate material, including, but not limited to, silicones (such as polydimethylsiloxane), epoxies, and the like. It is understood that the boundary wall 178 not only secures the heat dissipation device 160 to the substrate 140, but also maintains a desired distance (e.g. bond line thickness BLT₁ and BLT₂) between the first surface 174 of the heat dissipation device 160 and second surfaces 124₁, 124₂ of the integrated circuit devices 120₁, 120₂, respectively.

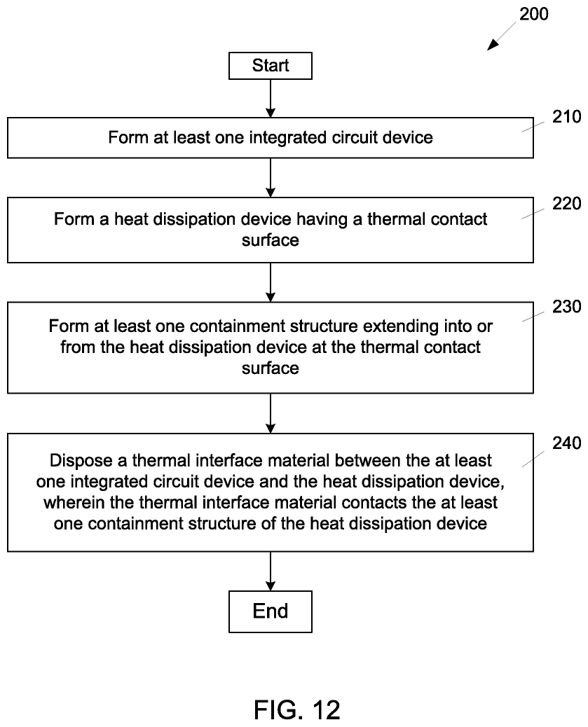

FIG. 12 is a flow chart of a process 200 of fabricating an integrated circuit assembly according to an embodiment of the present description. As set forth in block 210, at least one integrated circuit device may be formed. A heat dissipation device having a thermal contact surface may be formed, as set forth in block 220. As set forth in block 230, at least one containment structure may be formed to extend into or from the heat dissipation device at the thermal contact surface. A thermal interface material may be disposed between the at least one integrated circuit device and the heat dissipation device, wherein the thermal interface material contacts the at least one containment structure of the heat dissipation device, as set forth in block 240.

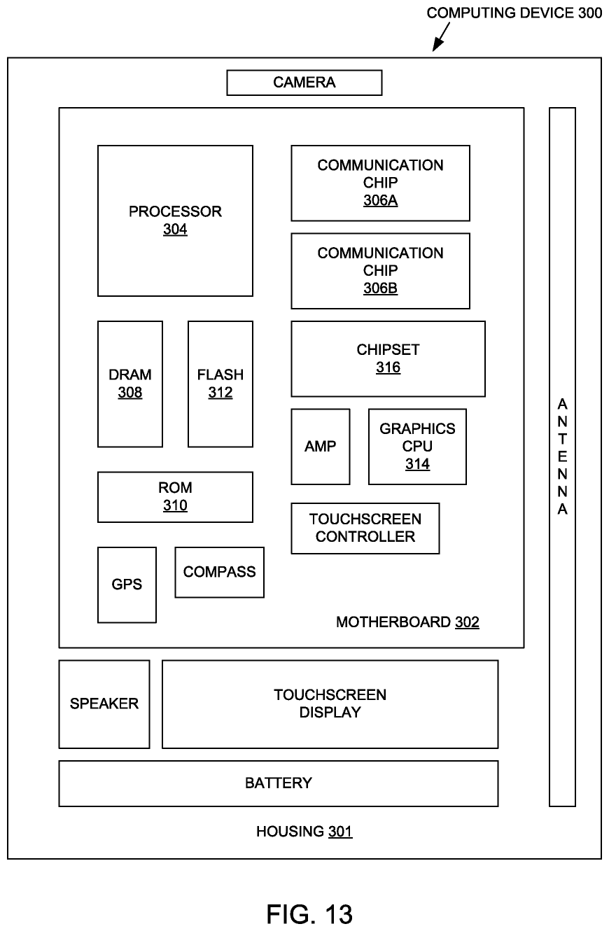

FIG. 13 illustrates an electronic or computing device 300 in accordance with one implementation of the present description. The computing device 300 may include a housing 301 having a board 302 disposed therein. The computing device 300 may include a number of integrated circuit components, including but not limited to a processor 304, at least one communication chip 306A, 306B, volatile memory 308 (e.g., DRAM), non-volatile memory 310 (e.g., ROM), flash memory 312, a graphics processor or CPU 314, a digital signal processor (not shown), a crypto processor (not shown), a chipset 316, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 302. In some implementations, at least one of the integrated circuit components may be a part of the processor 304.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include an integrated circuit assembly comprising at least one integrated circuit device, a heat dissipation device having a thermal contact surface with at least one containment structure extending into or from the heat dissipation device at the thermal contact surface, and a thermal interface material between the at least one integrated circuit device and the heat dissipation device, wherein the thermal interface material contacts the at least one containment structure of the heat dissipation device.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-13. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is an integrated circuit assembly, comprising at least one integrated circuit device, a heat dissipation device having a thermal contact surface with at least one containment structure extending into or from the heat dissipation device at the thermal contact surface, and a thermal interface material between the at least one integrated circuit device and the heat dissipation device, wherein the thermal interface material contacts the at least one containment structure of the heat dissipation device.

In Example 2, the subject matter of Example 1 can optionally include the at least one containment structure comprising at least one recess extending into the heat dissipation device from the thermal contact surface thereof.

In Example 3, the subject matter of any of Examples 1 to 2 can optionally include the at least one containment structure comprising at least one projection extending from the heat dissipation device at the thermal contact surface thereof.

In Example 4, the subject matter of any of Examples 1 to 3 can optionally include the heat dissipation device being selected from the group consisting of a heat pipe, a vapor chamber, a liquid cooling device, and a cold plate.

In Example 5, the subject matter of any of Examples 1 to 4 can optionally include an electronic substrate, wherein least one integrated circuit device is electrically attached to the electronic substrate.

In Example 6, the subject matter of Example 5 can optionally include the heat dissipation device including a main body having the thermal contact surface and a boundary wall extending from the thermal contact surface of the main body of the heat dissipation device, and wherein the boundary wall is attached to the electronic substrate.

Example 7 is an electronic system, comprising a board and an integrated circuit package electrically attached to the board, wherein the integrated circuit package comprises an integrated circuit assembly, comprising at least one integrated circuit device, a heat dissipation device having a thermal contact surface with at least one containment structure extending into or from the heat dissipation device at the thermal contact surface, and a thermal interface material between the at least one integrated circuit device and the heat dissipation device, wherein the thermal interface material contacts the at least one containment structure of the heat dissipation device.

In Example 8, the subject matter of Example 7 can optionally include the at least one containment structure comprising at least one recess extending into the heat dissipation device from the thermal contact surface thereof.

In Example 9, the subject matter of any of Examples 7 to 8 can optionally include the at least one containment structure comprising at least one projection extending from the heat dissipation device at the thermal contact surface thereof.

In Example 10, the subject matter of any of Examples 7 to 9 can optionally include the heat dissipation device being selected from the group consisting of a heat pipe, a vapor chamber, a liquid cooling device, and a cold plate.

In Example 11, the subject matter of any of Examples 7 to 10 can optionally include an electronic substrate, wherein least one integrated circuit device is electrically attached to the electronic substrate.

In Example 12, the subject matter of Example 11 can optionally include the heat dissipation device including a main body having the thermal contact surface and a boundary wall extending from the thermal contact surface of the main body of the heat dissipation device, and wherein the boundary wall is attached to the electronic substrate.

Example 13 is a method of fabricating an integrated circuit assembly, comprising forming at least one integrated circuit device, forming a heat dissipation device having a thermal contact surface, forming at least one containment structure extending into or from the heat dissipation device at the thermal contact surface, and disposing a thermal interface material between the at least one integrated circuit device and the heat dissipation device, wherein the thermal interface material contacts the at least one containment structure of the heat dissipation device.

In Example 14, the subject matter of Example 13 can optionally include forming the at least one containment structure comprising forming at least one recess extending into the heat dissipation device from the thermal contact surface thereof.

In Example 15, the subject matter of any of Examples 13 to 14 can optionally include forming the at least one containment structure comprising forming at least one projection extending from the heat dissipation device at the thermal contact surface thereof.

In Example 16, the subject matter of any of Examples 13 to 15 can optionally include forming the heat dissipation device being selected from the group consisting of forming a heat pipe, forming a vapor chamber, forming a liquid cooling device, and forming a cold plate.

In Example 17, the subject matter of any of Examples 13 to 16 can optionally include forming the at least one containment structure being a process selected from the group consisting of etching, laser scribing, ion ablation, stamping, skiving, and molding.

In Example 18, the subject matter of any of Examples 13 to 17 can optionally include forming an electronic substrate and electrically attaching the least one integrated circuit device to the electronic substrate.

In Example 19, the subject matter of Example 18 can optionally include electrically attaching the electronic substrate to the board.

In Example 20, the subject matter of Example 18 can optionally include forming the heat dissipation device including forming a main body having the thermal contact surface and a boundary wall extending from the thermal contact surface of the main body of the heat dissipation device, and attaching the boundary wall is attached to the electronic substrate.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. An integrated circuit assembly, comprising:
at least one integrated circuit device;
a heat dissipation device having a thermal contact surface with at least one containment structure extending into or from the heat dissipation device at the thermal contact surface; and
a thermal interface material between the at least one integrated circuit device and the heat dissipation device, wherein the thermal interface material contacts the at least one containment structure of the heat dissipation device.

2. The integrated circuit assembly of claim 1, wherein the at least one containment structure comprises at least one recess extending into the heat dissipation device from the thermal contact surface thereof.

3. The integrated circuit assembly of claim 1, wherein the at least one containment structure comprises at least one projection extending from the heat dissipation device at the thermal contact surface thereof.

4. The integrated circuit assembly of claim 1, wherein the heat dissipation device is selected from the group consisting of a heat pipe, a vapor chamber, a liquid cooling device, and a cold plate.

5. The integrated circuit assembly of claim 1, further comprising an electronic substrate, wherein the at least one integrated circuit device is electrically attached to the electronic substrate.

6. The integrated circuit assembly of claim 5, wherein the heat dissipation device includes a main body having the thermal contact surface and a boundary wall extending from the thermal contact surface of the main body of the heat dissipation device, and wherein the boundary wall is attached to the electronic substrate.

7. An electronic system, comprising:
a board;
an integrated circuit assembly electrically attached to the board, wherein the integrated circuit assembly comprises:
at least one integrated circuit device;
a heat dissipation device having a thermal contact surface with at least one containment structure extending into or from the heat dissipation device at the thermal contact surface; and
a thermal interface material between the at least one integrated circuit device and the heat dissipation device, wherein the thermal interface material contacts the at least one containment structure of the heat dissipation device.

8. The electronic system of claim 7, wherein the at least one containment structure comprises at least one recess extending into the heat dissipation device from the thermal contact surface thereof.

9. The electronic system of claim 7, wherein the at least one containment structure comprises at least one projection extending from the heat dissipation device at the thermal contact surface thereof.

10. The electronic system of claim 7, wherein the heat dissipation device is selected from the group consisting of a heat pipe, a vapor chamber, a liquid cooling device, and a cold plate.

11. The electronic system of claim 7, further comprising an electronic substrate, wherein the at least one integrated circuit device is electrically attached to the electronic substrate.

12. The electronic system of claim 11, wherein the heat dissipation device includes a main body having the thermal contact surface and a boundary wall extending from the thermal contact surface of the main body of the heat dissipation device, and wherein the boundary wall is attached to the electronic substrate.

13. A method of forming an integrated circuit assembly, comprising:
forming at least one integrated circuit device;
forming a heat dissipation device having a thermal contact surface;
forming at least one containment structure extending into or from the heat dissipation device at the thermal contact surface; and
disposing a thermal interface material between the at least one integrated circuit device and the heat dissipation device, wherein the thermal interface material contacts the at least one containment structure of the heat dissipation device.

14. The method of claim 13, wherein forming the at least one containment structure comprises forming at least one recess extending into the heat dissipation device from the thermal contact surface thereof.

15. The method of claim 13, wherein forming the at least one containment structure comprises forming at least one projection extending from the heat dissipation device at the thermal contact surface thereof.

16. The method of claim 13, wherein forming the heat dissipation device is selected from the group consisting of forming a heat pipe, forming a vapor chamber, forming a liquid cooling device, and forming a cold plate.

17. The method of claim 13, wherein forming at least one containment structure is a process selected from the group consisting of etching, laser scribing, ion ablation, stamping, skiving, and molding.

18. The method of claim 13, further comprising forming an electronic substrate and electrically attaching the at least one integrated circuit device to the electronic substrate.

19. The method of claim 18, further comprising electrically attaching the electronic substrate to the board.

20. The method of claim 18, wherein forming the heat dissipation device includes forming a main body having the thermal contact surface and forming a boundary wall extending from the thermal contact surface of the main body of the heat dissipation device, and attaching the boundary wall to the electronic substrate.
